(19) United States
(12) Patent Application Publication
(10) Pub. No.: US 2011/0140072 A1
(43) Pub. Date: Jun. 16, 2011

(54) DEFECT-FREE GROUP III - NITRIDE NANOSTRUCTURES AND DEVICES USING PULSED AND NON-PULSED GROWTH TECHNIQUES

(75) Inventors: Petros M. Varangis, Rio Rancho, NM (US); Lei Zhang, Albuquerque, NM (US)

(73) Assignee: NANOCRYSTAL CORPORATION, Rio Rancho, NM (US)

(21) Appl. No.: 13/059,409

(22) PCT Filed: Aug. 18, 2009
(86) PCT No.: PCT/US09/54181

§ 371 Date: Feb. 16, 2011

(30) Foreign Application Priority Data
Aug. 21, 2008 (US) 61090865

(51) Int. Cl. H01L 29/20; H01L 21/20; B82Y 99/00; B82Y 40/00

(52) U.S. Cl. 257/9; 438/503; 257/E21.09; 257/E29.089; 977/762

(57) ABSTRACT

Exemplary embodiments provide semiconductor devices including high-quality (i.e., defect free) Group III—Nitride nanostructures and uniform Group III—Nitride nanostructure arrays as well as their scalable processes for manufacturing, where the position, orientation, cross-sectional features, length and the crystallinity of each nanostructure can be precisely controlled. A pulsed growth mode can be used to fabricate the disclosed Group III—Nitride nanostructures and/or nanostructure arrays providing a uniform length of about 0.01-20 micrometers (μm) with constant cross-sectional features including an exemplary diameter of about 10 nanometers (nm)-500 micrometers (μm). Furthermore, core-shell nanostructure/MQW active structures can be formed by a core-shell growth on the non-polar sidewalls of each nanostructure and can be configured in nanoscale photoelectronic devices such as nanostructure LEDs and/or nanostructure lasers to provide tremendously-high efficiencies. Additional growth mode transitions from the pulsed to the non-pulsed growth mode and subsequent transitions from non-pulsed to pulsed growth mode are employed in order to incorporate certain group III—Nitride compounds more efficiently into the nanostructures and form devices of the designed shape, morphology and stochiometric composition. In addition, high-quality group III—Nitride substrate structures can be formed by coalescing the plurality of group III—Nitride nanostructures and/or nanostructure arrays to facilitate the fabrication of visible LEDs and lasers.

### FIELD OF THE INVENTION

This invention relates generally to Group III—Nitride semiconductor materials, including for example Gallium Nitride (GaN), Aluminum Nitride (AlN), Indium Nitride (InN), Aluminum Gallium Nitride (AlGaN), Indium Gallium Nitride (InGaN), and Aluminum Indium Gallium Nitride (AlInGaN), devices, and methods for their manufacture and, more particularly, relates to semiconductor nanostructures and semiconductor nanostructures active devices, such as light emitting diodes (LEDs) and laser diodes (LDs).

### BACKGROUND OF THE INVENTION

Nanostructures composed of Group III—Nitride alloys provide the potential for new semiconductor device configurations such as nanoscale optoelectronic devices. For example, GaN nanostructures can provide large bandgap, high melting point, and chemical stability that is useful for devices operating in corrosive or high-temperature environments. To fully realize this potential, a scalable process is needed for making high-quality Group III—Nitride nanostructures and/or nanostructure arrays with precise and uniform control of the geometry, position and/or crystallinity of each nanostructure.

Conventional nanostructure fabrication is based on a vapor-liquid-solid (VLS) growth mechanism and involves the use of catalysts such as Au, Ni, Fe, or In. Problems arise, however, because these conventional catalytic processes cannot control the position and uniformity of the resulting nanostructures. A further problem with conventional catalytic processes is that the catalyst is inevitably incorporated into the nanostructures. This degrades the crystalline quality of the resulting nanostructures, which limits their applications.

Thus, there is a need to overcome these and other problems of the prior art and to provide high-quality nanostructures and/or nanostructure arrays, and scalable methods for their manufacturing. It is further desirable to provide nanostructure photoelectronic devices and their manufacturing based on the high-quality nanostructures and/or nanostructure arrays.

### SUMMARY OF THE INVENTION

According to various embodiments, the present teachings include a method of making nanostructures. In the method, a selective growth mask can be formed over a substrate. The selective growth mask can include a plurality of patterned apertures that expose a plurality of portions of the substrate. A semiconductor material can then be grown on each of the plurality of portions of the substrate exposed in each of the patterned apertures using a Selective Area non-pulsed growth mode. The growth mode can be transitioned from the Selective Area non-pulsed growth mode to a pulsed growth mode. By continuing the pulsed growth mode of the semiconductor material, a plurality of semiconductor nanostructures can be formed. Further transistions between pulsed and non-pulsed growth modes can be used advantageously to form these semiconductor nanostructures.

According to various embodiments, the present teachings also include a Group III—Nitride nanostructure array, in accordance with the growth methods described above, which array can include a selective area growth mask disposed over a substrate. The selective growth mask can include a plurality of patterned apertures that expose a plurality of portions of the substrate. A Group III—Nitride nanostructure can be connected to and extend from the exposed plurality of portions of the substrate and extend over the top of the selective growth mask. The group III—Nitride nanostructure can be oriented along a single direction and can maintain a cross-sectional feature of one of the plurality of selected surface regions.

According to various embodiments, the present teachings further include a Group III—Nitride semiconductor substrate, for example grown as described above. The substrate structure can be a Group III—Nitride semiconductor film coalesced from a plurality of Group III—Nitride nanostructures, which is defect free. The Group III—Nitride film can have a defect density of about 100 million defects per centimeter square (cm⁻²) or lower.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate several embodiments of the invention and together with the description, serve to explain the principles of the invention.

FIGS. 1A-1C depict cross-sectional views of an exemplary semiconductor nanostructure device at various stages of fabrication in accordance with the present teachings.

FIG. 2 depicts a second exemplary semiconductor nanostructure device in accordance with the present teachings.

FIG. 3 depicts an exemplary process for forming a plurality of nanostructures and/or nanostructure arrays using a multi-phase growth mode in accordance with the present teachings.

FIGS. 4A-4C depict a third exemplary semiconductor nanostructure device in accordance with the present teachings.

FIG. 5 depicts a forth exemplary semiconductor nanostructure device in accordance with the present teachings.

FIGS. 6A-6D depict exemplary results for a plurality of ordered GaN nanostructure arrays grown without use of a catalyst.

FIGS. 7A-7D depict four exemplary variants of semiconductor devices including GaN substrate structures formed from the plurality of nanostructures and/or nanostructure arrays shown in FIGS. 1-6 in accordance with the present teachings.

FIG. 8 depicts an exemplary core-shell nanostructure/MQW (multiple quantum well) active structure device in accordance with the present teachings.

FIG. 9 depicts another exemplary core-shell nanostructure/MQW active structure device in accordance with the present teachings.

FIGS. 10A-10C depict an exemplary nanostructure LED device formed using the core-shell nanostructure/MQW active structure described in FIGS. 8-9 in accordance with the present teachings.

FIG. 11 depicts an exemplary nanostructure laser device using the core-shell nanostructure/MQW active structure described in FIGS. 8-9 in accordance with the present teachings.

FIG. 12 depicts another exemplary nanostructure laser device using the core-shell nanostructure/MQW active structure described in FIGS. 8-9 in accordance with the present teachings.

### DESCRIPTION OF THE EMBODIMENTS

Reference will now be made in detail to exemplary embodiments of the invention, examples of which are illustrated in the accompanying drawings. Wherever possible, the same reference numbers will be used throughout the drawings to refer to the same or like parts. In the following description, reference is made to the accompanying drawings that form a part thereof, and in which is shown by way of illustration specific exemplary embodiments in which the invention may be practiced. These embodiments are described in sufficient detail to enable those skilled in the art to practice the invention and it is to be understood that other embodiments may be utilized and that changes may be made without departing from the scope of the invention. The following description is, therefore, merely exemplary.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.” The term “at least one of” is used to mean one or more of the listed items can be selected.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

Exemplary embodiments provide semiconductor devices including high-quality (i.e., defect free) Group III—Nitride nanostructures and uniform Group III—Nitride nanostructure arrays as well as scalable processes for their manufacturing, where the position, orientation, cross-sectional features, length and/or the crystallinity of each nanostructure can be precisely controlled. Specifically, a plurality of nanostructures and/or nanostructure arrays can be formed using a Selective Growth non-pulsed mode followed by a growth-mode-transition from the Selective Growth non-pulsed mode to a pulsed growth mode. The cross-sectional features, for example, the cross-sectional dimensions (e.g., diameter or width), and the cross-sectional shapes, of each nanostructure obtained from the selective growth mode can be maintained by continuing the growth using the pulsed growth mode. In this manner, nanostructures with a high aspect ratio can be formed. In an exemplary embodiment, the length of each nanostructure can be, for example, about 10 nm to about 20 micrometers (μm), or more. After the pulsed growth mode, further growth includes additional transitions between pulsed and non-pulsed growth modes.

In addition, high-quality Group III—Nitride films, for example, high-quality GaN films, can be formed by terminating and coalescing the plurality of nanostructures and/or nanostructure arrays. These GaN films can be used as GaN substrate structures to facilitate the fabrication of visible LEDs and lasers for the emerging solid-state lighting and UV sensor industries.

Furthermore, because each of the nanostructures and/or arrays can provide nonpolar sidewalls, a core-shell growth can be realized on each nanostructure with an MQW active shell structure formed thereon. Such core-shell nanostructure/MQW active structures can be used in nanoscale photoelectronic devices, such as, for example, nanostructure LEDs and/or nanostructure lasers having high efficiencies.

As used herein, the term “nanostructure” generally refers to any elongated conductive or semiconductive material that includes at least one minor dimension, for example, one of the cross-sectional dimensions such as width or diameter, of less than or equal to about 100 micrometers (μm). In various embodiments, the minor dimension can be less than about 100 nm. In various other embodiments, the minor dimension can be less than about 10 nm. The nanostructures can have an aspect ratio (e.g., length: width and/or major dimension: minor dimension) of about 100 or greater. In various embodiments, the aspect ratio can be about 200 or greater. In various other embodiments, the aspect ratio can be about 2000 or greater. In an exemplary embodiment the cross-section of the nanostructure can be highly asymmetric such that in one direction of the cross-sectional dimension can be much less than 1000 nanometers (nm) and in an orthogonal direction the dimension can be substantially greater than 1000 nm.

It is also intended that the term “nanostructures” also encompass other elongated structures of like dimensions including, but not limited to, nanoshafts, nanopillars, nanoneedles, nanorods, and nanotubes (e.g., single wall nanotubes, or multiwall nanotubes), and their various functionalized and derivatized fibril forms, such as nanofibers in the form of thread, yarn, fabrics, etc.

The nanostructures can have various cross-sectional shapes, such as, for example, rectangular, polygonal, square, oval, or circular shape. Accordingly, the nanostructures can have cylindrical and/or cone-like three dimensional (3-D) shapes. In various embodiments, a plurality of nanostructures can be, for example, substantially parallel, arcuate, sinusoidal, etc., with respect to each other.

The nanostructures can be formed on/from a support, which can include selected surface regions where the nanostructures can be connected to and extend (e.g., be grown) from. The support of the nanostructures can also include a substrate formed from a variety of materials including Si, SiC, sapphire, III-V semiconductor compounds such as GaN or GaAs, metals, ceramics or glass. The support of the nanostructures can also include a selective growth mask formed on the substrate. In various embodiments, the support of the nanostructures can further include a buffer layer disposed between the selective growth mask and the substrate.

In various embodiments, nanostructure active devices, for example, nanostructure LEDs or nanostructure lasers, can be formed using the nanostructures and/or nanostructure arrays. In various embodiments, the nanostructures and/or nanostructure arrays and the nanostructure active devices can be formed using a III-V compound semiconductor materials system, for example, the Group III—Nitride compound materials system. Examples of the group III elements can include Ga, In, or Al, which can be formed from exemplary group III precursors, such as trimethylgallium (TMGa) or triethylgallium (TEGa), trimethylindium (TMIn) or trimethylaluminum (TMAl). Exemplary group V precursors can be Nitrogen (N) precursors, for example, ammonia (NH₃). Other group V elements can also be used, for example, P or As, with exemplary group V precursors, such as tertiarybutylphoshine (TBP), or arsine (AsH₃).

In the following description, Group III—Nitride semiconductor alloy compositions can be described by the combination of Group III—Nitride elements, such as, for example, GaN, AlN, InN, InGaN, AlGaN, or AlInGaN. Generally, the elements in a composition can be combined with various molar fractions. For example, the semiconductor alloy composition InGaN can stand for InₓGa_{1-X}N, where the molar fraction, x, can be any number less than 1.00. In addition, depending on the molar fraction value, various active devices can be made by similar compositions. For example, an In_{0.3}Ga_{0.7}N (where x is about 0.3) can be used in the MQW active region of LEDs for a blue light emission, while an In_{0.43}Ga_{0.57}N (where x is about 0.43) can be used in the MQW active region of LEDs for a green light emission.

In various embodiments, the nanostructures, nanostructure arrays, and/or the nanostructure active devices can include a dopant from a group consisting of: a p-type dopant from Group III of the periodic table, for example B, Al and In; an n-type dopant from Group V of the periodic table, for example, P, As and Sb; a p-type dopant from Group II of the periodic table, for example, Mg, Zn, Cd and Hg; a p-type dopant from Group IV of the periodic table, for example, C; or an n-type dopant selected from a group consisting of: Si, Ge, Sn, S, Se and Te.

In various embodiments, the nanostructures and/or nanostructure arrays as well as the nanostructure active devices can have high-quality heterogeneous structures and be formed by various crystal growth techniques including, but not limited to, metal-organic chemical vapor deposition (MOCVD), molecular-beam epitaxy (MBE), gas source MBE (GSMBE), metal-organic MBE (MOMBE), atomic layer epitaxy (ALE), hydride vapor phase epitaxy (HVPE), or organometallic vapor phase epitaxy (OMVPE). When a Group III—Nitride semiconductor is to be grown by one of the aforementioned methods the molar ratio of a nitrogen source or precursor gas to a Group III source or precursor gas is usually referred to as VIII ratio.

In various embodiments, a multiple-phase growth mode, for example, a three-phase growth mode, can be used for the high-quality crystal growth of nanostructures and/or nanostructure arrays as well as nanostructure active devices. For example, a first phase growth mode such as a selective non-pulsed growth mode can be used to provide a condition for growth selectivity and nucleation of the nanostructures and/or nanostructure arrays. In the selective non-pulsed growth mode, standard crystal growth methods, for example, standard MOCVD, can be used to nucleate the growth of the nanostructures with a desired thickness of, for example, about 10 nm or more.

The second phase growth mode can create a close-to-equilibrium growth process to continue the growth of each nanostructure and maintain its cross-sectional features from the first growth mode, and also provide an arbitrary desired length. The second phase growth mode can be applied by a growth-mode-transition, which can terminate the first phase growth mode. In the second phase growth mode, a pulsed growth mode can be used.

As used herein, the term “pulsed growth mode” refers to a process in which the group III and group V precursor gases are introduced alternately in a crystal growth reactor with a designated sequence. For example, TMGa and NH₃ can be used as the precursors for an exemplary formation of GaN nanostructures and/or nanostructure arrays and/or GaN nanostructure active devices. In the pulsed growth mode TMGa and NH3 can be introduced alternately in a sequence that introduces TMGa with a designed flow rate (e.g., 10 sccm or any other value) for a certain period of time (e.g., 20 seconds or any other value) followed by the introduction into the chamber of NH3 with a designed flow rate (e.g., 1500 sccm or any other value) for a certain period of time (e.g., 30 seconds or any other value). In various embodiments one or more sequence loops will be conducted (e.g., repeated) for a designed length of each nanostructure. In various embodiments, the growth rate of each nanostructure can be orientation dependent.

The second phase pulsed growth mode can be followed by a third phase non-pulsed mode. Further transitions between pulsed and non-pulsed can also be used.

In various embodiments, dielectric materials can be involved in the disclosed nanostructures, nanostructure arrays, and/or nanostructure active devices. For example, the selective growth mask can be made of dielectric materials during the formation of the plurality of nanostructures and/or nanostructure arrays. In another example, dielectric materials can be used for electrical isolation for active devices such as nanostructure LEDs and/or nanostructure lasers. As used herein, the dielectric materials can include, but are not limited to, silicon oxide (SiO₂), silicon nitride (Si₃N₄), silicon oxynitride (SiON), fluorinated silicon dioxide (SiOF), silicon oxycarbide (SiOC), hafnium Oxide (HfO₂), hafnium-silicate (HfSiO), nitride hafnium-silicate (HfSiON), zirconium oxide (ZrO₂), aluminum oxide (Al₂O₃), barium strontium titanate (BST), lead zirconate titanate (PZT), zirconium silicate (ZrSiO₂), tantalum oxide (TaO₂) or other insulating materials.

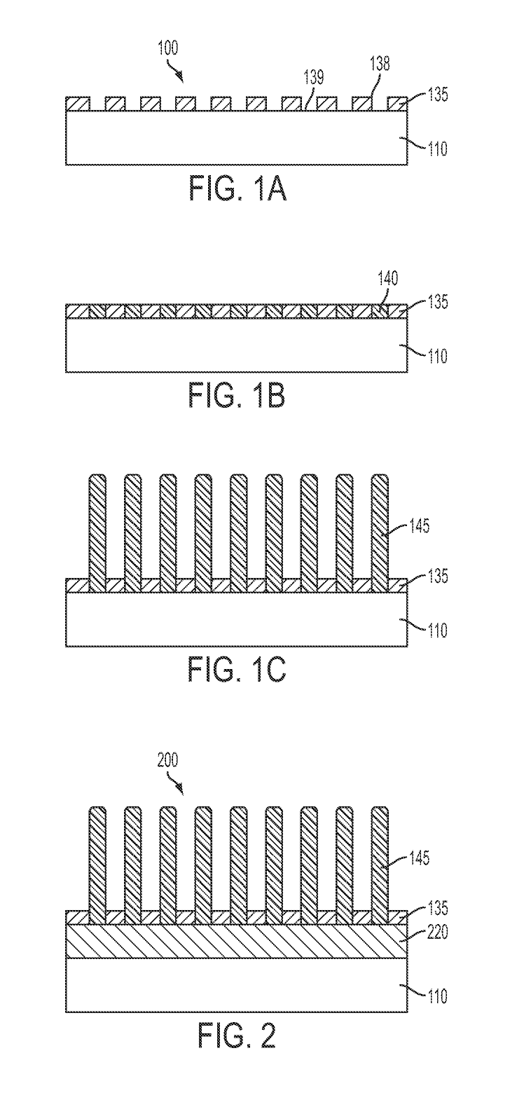

Exemplary embodiments for semiconductor devices of nanostructures and/or nanostructure arrays and their scaleable processes for growth are shown in FIGS. 1A-1C, FIGS. 2-3, FIGS. 4A-4C, FIG. 5, and FIGS. 6A-6D.

FIGS. 1A-1C depict cross-sectional views of an exemplary semiconductor nanostructure device 100 at various stages of fabrication in accordance with the present teachings. It should be readily apparent to one of ordinary skill in the art that the nanostructure device 100 depicted in FIGS. 1A-1C represents a generalized schematic illustration and that other layers/nanostructures may be added or existing layers/nanostructures may be removed or modified.

As shown in FIG. 1A, the nanostructure device 100 can include a substrate 110, a selective growth mask 135, and a plurality of patterned apertures 138. The selective growth mask 135 and the plurality of patterned apertures 138 can be disposed over the substrate 110, wherein the plurality of patterned apertures 138 can be interspersed through the selective growth mask 135.

The substrate 110 can be any substrate on which a Group III—Nitride material can be grown. In various embodiments, the substrate 110 can include, but is not limited to, sapphire, silicon carbide, silicon, silicon-on-insulator (SOI), Group III—Group V semiconductor compounds such as GaN or GaAs, metals, ceramics or glass.

The selective growth mask 135 can be formed by patterning and etching a dielectric layer (not shown) formed over the substrate 110. In various embodiments, the dielectric layer can be made of any dielectric material and formed using techniques known to one of ordinary skill in the art. The dielectric layer can then be patterned using one or more of interferometric lithography (IL) including immersion interferometric lithography and nonlinear interferometric lithography, nanoimprint lithography (NL), and e-beam lithography, which can produce nanostructures or patterns of nanostructures over wide and macroscopic areas. After the patterning, an etching process, for example, a reactive ion etching, can be used to form the plurality of patterned apertures 138. The etching process can be stopped at the surface of the underlying layer, i.e., the substrate 110, and exposing a plurality of surface portions 139 of the substrate 110. In various embodiments the selective growth mask 135 can be a metal growth mask made of, for example, tungsten, to provide selective growth of nanostructures as desired by the pulsed growth mode.

The plurality of patterned apertures 138 can have a thickness the same as the selective growth mask 135, for example, about 30 nm or less, and a cross-sectional dimension, such as a diameter, of about 10 nm to about 10 μm. As an additional example, the diameter can be about 10 to about 1000 nm. In an exemplary embodiment, the plurality of patterned apertures 138 can have a hexagonal array with a pitch (i.e., center-to-center spacing between any two adjacent patterned apertures) ranging from about 50 nm to about 100 micrometers (μm). In various embodiments, arrays of the plurality of patterned apertures 138 can be formed. Thereafter, the nanoscale features of the plurality of the patterned apertures 138 can be transferred to the subsequent processes for the formation of nanostructures and/or nanostructure arrays.

In various embodiments, various cleaning procedures can be conducted on the device 100 shown in FIG. 1A prior to the subsequent growth of the nanostructures and/or nanostructure arrays. For example, the cleaning processes can include an ex-situ cleaning (i.e., the cleaning is conducted outside the growth reactor) followed by an in-situ cleaning (i.e., the cleaning is conducted within the growth reactor). Depending on materials used for the selective growth mask 135, various cleaning methods can be used. In an exemplary embodiment, a silicon nitride selective growth mask can be cleaned by a standard ex-situ cleaning followed by an in-situ cleaning by loading the device 100 into an exemplary MOCVD reactor and heating the device 100 to about 950° C. for approximately 3 minutes under flowing hydrogen. This hydrogen-reducing-atmosphere can remove undesirable native oxides on the surfaces of the device 100. Depending on the material combination of the substrate 110 and the selective growth mask 135, one of ordinary skill in the art will understand that alternative cleaning procedures can be used.

In FIG. 1B, a plurality of nanostructure nuclei 140 can be selectively grow from the exposed plurality of surface portions 139 of the substrate 110 to fill each of the plurality of patterned apertures 138, which can be defined by the selective growth mask 135. The selective growth mask 135 can serve as a selective growth mold to negatively replicate its nanopatterns from the plurality of patterned apertures 138 to the plurality of nanostructure nuclei 140. In this manner, the position and the cross-sectional features, such as the shape and dimensions, of each of the plurality of nanostructure nuclei 140 can be determined by that of each patterned aperture of the plurality of patterned apertures 138. For example, the plurality of patterned apertures 138 can include a hexagonal array with a dimension of about 250 nm. The hexagonal array can then be transferred to the growth of the plurality of nanostructure nuclei 140 with a similar or smaller dimension of about 250 nm or less. In another example, if the one or more apertures of the plurality of patterned apertures 138 are approximately circular with an exemplary diameter of about 100 nm, one or more nuclei of the plurality of nanostructure nuclei 140 can be grown in the circular apertures with a similar diameter of about 100 nm or less. Thus, the plurality of nanostructure nuclei 140 can be positioned in a well-defined location and shaped correspondingly to the plurality of the patterned apertures 138 defined by the selective growth mask 135. In various embodiments, the plurality of nanostructure nuclei 140 can be formed by, for example, a standard MOCVD process.

In this manner, the device 100 shown in FIG. 1B can be used as a support for nanostructures and/or nanostructure arrays, which can include a plurality of selected surface regions (i.e., each surface of the plurality of nanostructure nuclei 140). A plurality of nanostructures and/or nanostructure arrays can then be grown from the plurality of selected surface regions. In various embodiments, the selective growth mask 135 can be removed by a suitable etching process to expose the plurality of nanostructure nuclei 140 after the formation of the plurality of the nanostructures.

In FIG. 1C, a plurality of nanostructures 145 can be formed by continuing the growth of the plurality of nanostructure nuclei 140 by, for example, terminating the selective non-pulsed growth mode and applying a pulsed growth mode, before the plurality of nanostructure nuclei 140 protrudes from a top of the selective growth mask 135. The plurality of nanostructures 145 can be formed of the same material of the nanostructure nuclei 140, for example, GaN, AlN, InN, InGaN, AlInGaN, or AlGaN. In various embodiments, heterostructures can be formed from each of the plurality of nanostructures 145. In various embodiments, n-type and/or p-type dopants can be incorporated into the plurality of nanostructures 145 depending on the desired application.

By transitioning to the pulsed growth mode before growth of the plurality of nanostructure nuclei 140 protrudes from the top of the selective growth mask 135, features such as cross-sectional shape and dimensions of each of the plurality of nanostructures 145 can be preserved until a desired length is reached. In other words, the cross-sectional features of the nanostructures 145, such as shape and/or dimension, can remain substantially constant, the same or similar as that of the apertures 138. In various embodiments, the length of each nanostructure can be on an order of micrometers, for example, about 20 μm or more.

After the initial growth of nanostructures 145 is completed, one or more subsequent growth mode transitions from the pulsed growth mode to the non-pulsed growth mode, as well as subsequent growth mode transitions from the non-pulsed growth mode to the pulsed growth mode, are performed in order to more effectively incorporate group III—Nitride semiconductor compounds, such as GaN, AlN, InN, InGaN, AlInGaN, or AlGaN, into the structure of the nanostructures 145 and in order to form nanostructures 145 of the designed shape, size, diameter, length, morphology and stochiometric composition.

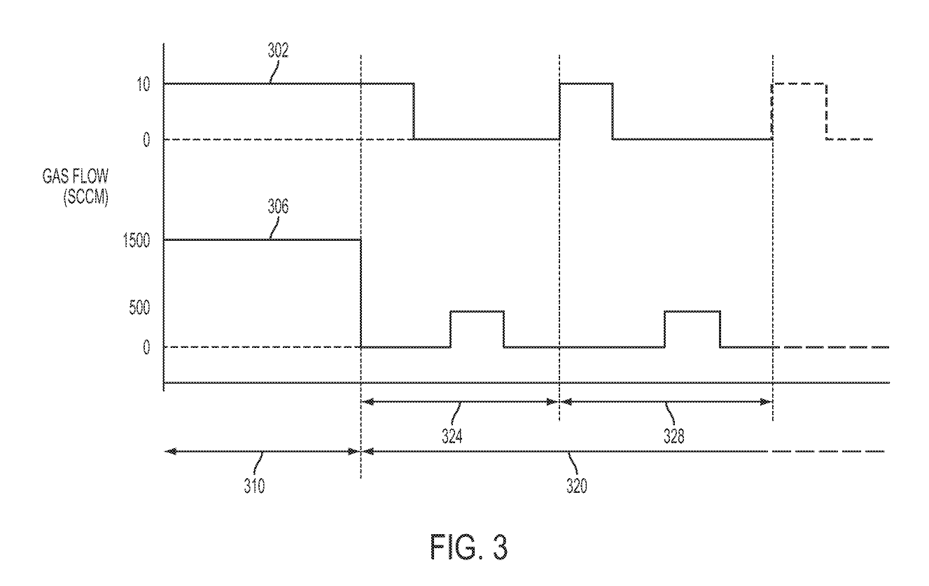

In various embodiments, a buffer layer can be formed in the nanostructure devices. FIG. 2 depicts a second exemplary semiconductor nanostructure device 200 including a buffer layer in accordance with the present teachings. As shown, the nanostructure device 200 can include a buffer layer 220 disposed between a substrate such as the substrate 110 and a selective growth mask such as the selective growth mask 135 (see FIGS. 1A-1C). In various embodiments, the buffer layer 220 can be a planar semiconductor film formed of, for example, GaN, AlN, InN, InGaN, AlInGaN or AlGaN, by, for example, standard MOCVD. In various embodiments, the thickness of the buffer layer 220 can be, for example, about 100 nm to about 10 micrometers (μm). In various embodiments the buffer layer 220 can be doped with either an n-type or a p-type dopant in order to provide an electrical connection to the lower end of each nanostructure of the plurality of nanostructures 140. Various dopants known to one of ordinary skill can be used.

In various embodiments, the orientation of the plurality of nanostructure nuclei 140 can be controlled along a single direction, which can in turn be controlled by intentionally orienting the plurality of patterned apertures 138 along the single crystal direction. For example, the plurality of patterned apertures 138 can be intentionally oriented along a single direction of the buffer layer 220 as shown in FIG. 2. In an exemplary embodiment during interferometric lithography or imprint lithography patterning, the apertures in the selective growth mask 135 can be intentionally oriented along the <1100> direction of a GaN buffer layer. In another exemplary embodiment when the GaN buffer layer is grown on a sapphire substrate, there can be a 30° rotation about the c axis between the GaN buffer layer and the sapphire unit cells.

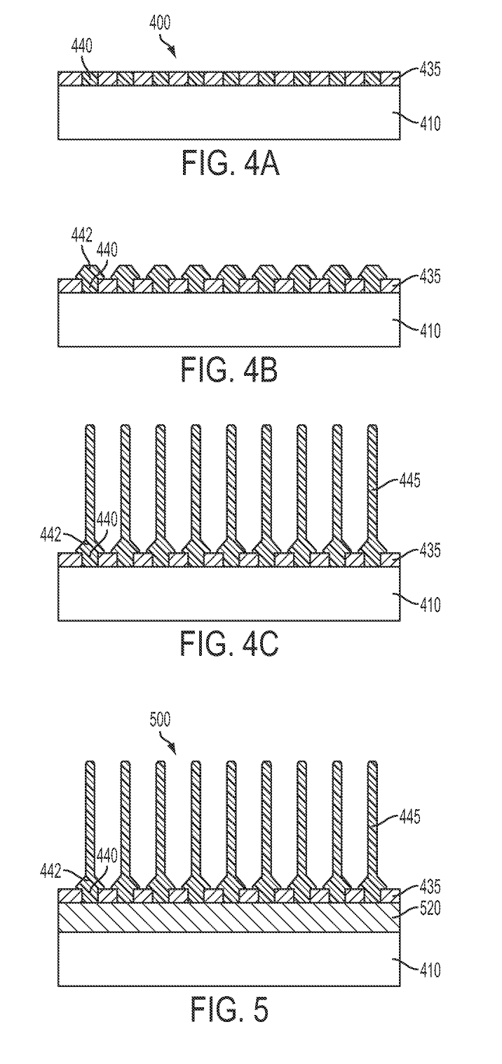

FIG. 3 depicts an exemplary process for the first two phases of growth in accordance with the present teachings. Specifically, FIG. 3 illustrates precursor gas flow curves (including a first gas flow curve 302 corresponding to the Group III precursor and a second gas flow curve 306 corresponding to the Group V precursor) during a selective non-pulsed growth 310 and a subsequent pulsed growth mode 320 for the formation of, for example, the plurality of nanostructures 145 as described in FIGS. 1-2. As shown, the selective non-pulsed growth 310 can be terminated by starting a pulsed growth mode 320 (i.e., growth-mode-transition) at a transition time t₁. Subsequent growth can provide further transitions between non-pulsed and pulsed growth.

In an exemplary embodiment for the formation of GaN nanostructures and/or nanostructure arrays, the first gas flow curve 302 can be plotted for a first precursor gas such as trimethylgallium (TMGa), and the second gas flow curve 306 can be plotted for a second precursor gas such as ammonia (NH₃). During the selective non-pulsed growth 310, the exemplary GaN nanostructures and/or nanostructure arrays can be formed in a MOCVD reactor including the first precursor gas TMGa with a constant flow rate of about 10 sccm or any other value, and the second precursor gas NH₃ with a constant flow rate of about 1500 sccm or any other value. That means, during the selective non-pulsed growth 310, the precursor gases (i.e., TMGa and NH₃) can be flowed continuously, not pulsed. Moreover, the group III precursor gas (e.g., TMGa) and group V precursor gas (e.g. NH₃) can be introduced simultaneously and the group V/group III ratio can be maintained, for example, at about 150 or any other value. In an exemplary embodiment, the group V/group III ratio can be maintained at about 1500. Further, other reactor conditions for the selective growth 310 can include, for example, an initial reaction temperature of about 1015° C., a reactor pressure of about 100 Torr, and a hydrogen/nitrogen carrier gas mixture having a laminar flow of about 4000 sccm. Any suitable MOCVD reactor may be used, such as the Veeco TurboDisk Model P75 MOCVD reactor in which the substrates are rotated at high speed during deposition.

During pulsed growth 320, the first precursor gas such as TMGa and the second precursor gas such as NH₃ can be introduced alternately into the growth reactor in a designed sequence, for example, shown as the first sequence loop 324. In various embodiments, the duration of each alternating step within the pulsed sequence can affect the growth of the nanostructures and/or nanostructure arrays, which can further be optimized for specific reactor geometries. For example, in the first pulsed sequence loop 324, TMGa can be introduced with a flow rate of about 10 sccm for a certain period of time such as about 20 seconds (not illustrated) followed by introducing NH₃ with a flow rate of about 1500 sccm for a time period such as about 30 seconds (not illustrated). In various embodiments, the pulsed sequence such as the first sequence loop 324 can be repeated until a certain length of the GaN nanostructures is reached. For example, the sequence loop 324 can be repeated as the second sequence loop 328, the third sequence loop (not illustrated) and so on. In each sequence loop, the group III precursor gases (e.g., TMGa, TEGa, TMIn, TMAl etc) and group V precursor gas (e.g. NH₃) can have a VIII ratio in a range of, for example, from about 50 to 5000, or any other value. In various embodiments, the temperature, reactor pressure, and carrier gas flow for the pulsed growth 320 can remain at their same settings as for the selective growth 310. One of ordinary skill in the art will understand that the disclosed growth parameters are exemplary and can vary depending on the specific reactor used.

In various embodiments, the transition time (t₁) can be determined by the duration of the selective growth 310. The transition time (t₁) can be dependent on the growth rate inside each aperture, for example, each of the plurality of patterned apertures 138 shown in FIGS. 1-2. The growth rate inside each aperture can in turn depend on the gas flows (e.g., shown as gas flow curves 302 and 306) of each precursor gas and the geometry of each aperture of the plurality of patterned apertures 138. This geometrical dependence can occur because the growth nutrients, for example, from TMGa and/or NH₃, can be deposited both on the selective growth mask and in the open apertures. During selective non-pulsed growth 310, the nutrient that deposits on the selective growth mask can have a high surface mobility and can either leave the mask surface or, if it is close enough to an open aperture, diffuse to that aperture and contribute to the growth rate in that aperture. This additional growth rate contribution can therefore vary based on the size of the apertures and the distance between the apertures. In an exemplary embodiment for forming a plurality of GaN nanostructures and/or nanostructure arrays, the growth-mode-transition can occur after a 1 minute duration of the selective growth (i.e., t₁=1 minute), which can be experimentally determined by the GaN growth rate inside the patterned apertures. For example, the GaN growth rate can be about 0.6 μm/hr and the patterned apertures can be in the form of a hexagonal array having a diameter of about 200 nm and a pitch of about 1 mm.

In various embodiments, the growth of the plurality of nanostructures and/or nanostructure arrays can be affected by when the first growth-mode-transition from the non-pulsed growth mode to the pulsed growth mode is applied. For example, the growth-mode-transition can be applied after growth of the plurality of nanostructure nuclei 140 protrude over the top of the selective growth mask (such as 135 seen in FIGS. 1-2). In various embodiments, different configurations/dimensions can be obtained for the nanostructures and/or nanostructure arrays, depending on whether the growth-mode-transition is applied “before” (e.g., as shown in FIGS. 1-2) or “after” the nanostructure nuclei have grown to protrude over the top of the selective growth mask.

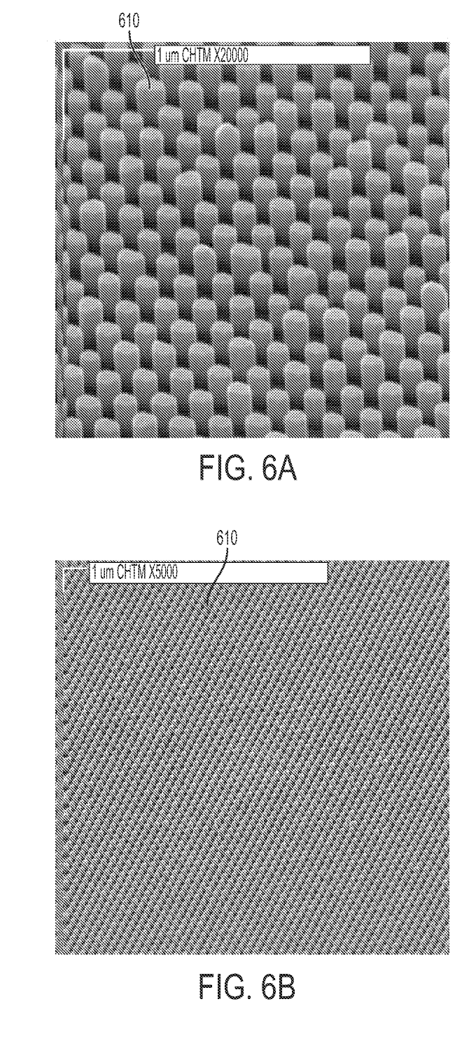

FIGS. 4A-4C depict a third exemplary semiconductor nanostructure device 400 formed by having a growth-mode-transition from a non-pulsed growth mode to a pulsed growth mode “after” the nanostructure nuclei have grown to protrude over the top of the selective growth mask (and then followed by subsequent transitions between pulsed and non-pulsed growth modes). It should be readily apparent to one of ordinary skill in the art that the nanostructure device 400 depicted in FIGS. 4A-4C represents a generalized schematic illustration and that other layers/nanostructures can be added or existing layers/nanostructures can be removed or modified.

In FIG. 4A, the device 400 can include a similar structure and be formed by a similar fabrication process as described in FIG. 1C for the device 100. As shown, the device 400 can include a substrate 410, a selective growth mask 435 and a plurality of nanostructure nuclei 440. The selective growth mask 435 and the plurality of nanostructure nuclei 440 can be formed over the substrate 110, wherein the plurality of nanostructure nuclei 440 can be interspersed through the selective growth mask 435.

The substrate 410 can be any substrate similar to the substrate 110 of the device 100, on which a Group III—Nitride material can be grown. The substrate 410 can be, for example, sapphire, silicon carbide, or silicon. Likewise, the plurality of nanostructure nuclei 440 can be formed similarly to that of the plurality of nanostructure nuclei 140 of the device 100 shown in FIG. 1B. For example, the plurality of nanostructure nuclei 440 can be formed by first forming a plurality of patterned apertures (not shown) defined by the selective growth mask 435 over the substrate 410. Each of the plurality of patterned apertures can then be filled by growing a semiconductor material (e.g., GaN) therein using, for example, standard MOCVD. The plurality of nanostructure nuclei 440 can have a thickness of the selective growth mask 435, for example, about 30 nm, and a cross-sectional dimension, such as a width or a diameter, of, for example, about 10 nm to about 10 micrometers (μm). And as an additional example, the width or diameter of the cross-sectional dimension can be about 10 nm to about 10 micrometers (μm).

In FIG. 4B, the device 400 can include a plurality of nanostructures 442 grown laterally as well as vertically from the plurality of nanostructure nuclei 440, when the growth-mode-transition from the non-pulsed growth mode to the pulsed growth mode occurs “after” the plurality of nanostructure nuclei 440 protrudes over the top of the selective growth mask 435. For example, each of the plurality of nanostructures 442 can be grown laterally, spreading sideways, and partially on the surface of the selective growth mask 435. In various embodiments, the plurality of nanostructures 442 can include a pyramid-shaped structure providing a top crystal facet. For example, a plurality of GaN pyramid-shaped nanostructures can include a (0001) top facet and the dimensions of this top facet can be controlled by the extent of the growth of each nanostructure. Specifically, at the early stage of the growth, when the plurality of nanostructures 442 is growing laterally, partially on the surface of the selective growth mask 435, the top facet dimensions can be increased and be broader than the cross-sectional dimensions of the plurality of nanostructure nuclei 440. When the growth is continued, the top facet dimensions can be decreased such that a point of the top facet dimensions can be smaller than that of the plurality of nanostructure nuclei 440. Therefore, the dimensions of each pyramid top facet can be controlled by, for example, a termination of the selective growth mode (i.e., to apply the growth-mode-transition) to stop the growth of the plurality of pyramid-shaped nanostructures. The top facet dimension can then be maintained for the subsequent growth of the nanostructures and/or nanostructure arrays using the pulsed growth mode. In various embodiments, the top facet diameter of each of the plurality of nanostructures 442 can be controlled to be smaller than that of each of the plurality of the nanostructure nuclei 440. In various embodiments, the top facet of each of the plurality of nanostructures 442 can have an exemplary cross-sectional shape of, for example, a square, a polygon, a rectangle, an oval, and a circle.

The device 400 shown in FIG. 4B can be used as a support of nanostructures and/or nanostructure arrays, which can also include a plurality of selected surface regions (i.e., the surface of each top facet of the plurality of nanostructures 442). A plurality of nanostructures and/or nanostructure arrays can then be grown from the plurality of selected surface regions and maintain the cross-sectional features (e.g., dimensions and shapes) of each of the plurality of selected surface regions.

In FIG. 4C, a plurality of nanostructures 445 can be formed by continuing the growth of the semiconductor material (e.g., GaN) from the plurality of selected surface regions of the device 400 (i.e., from each top facet of the plurality of nanostructures 442) using the pulsed growth mode. As a result, the plurality of nanostructures 445 can be regularly spaced and have an exemplary diameter ranging from about 10 nanometers (nm) to about 10 micrometers (μm) and an exemplary cross-sectional shape of, for example, a square, a polygon, a rectangle, an oval, and a circle.

By using the pulsed growth mode “after” the semiconductor material is grown to protrude over the top of the selective growth mask 435, the plurality of nanostructures 445 can be formed on the top facets of the exemplary pyramid-shaped structures of the plurality of nanostructures 442. Features such as cross-sectional shapes and dimensions of each of the plurality of nanostructures 445 can remain constant until a desired length is reached. In various embodiments, the length of each nanostructure can be controlled on an order of micrometers, such as, for example, about 20 μm or higher.

After the initial growth of nanostructures 445 is completed, one or more subsequent growth mode transitions from the pulsed growth mode to the non-pulsed growth mode, as well as subsequent growth mode transitions from the non-pulsed growth mode to the pulsed growth mode, are performed in order to more effectively incorporate group III—Nitride semiconductor compounds, such as GaN, AlN, InN, InGaN, AlInGaN, or AlGaN, into the structure of the nanostructures 445 and in order to form nanostructures 445 of the designed shape, size, diameter, length, morphology and stochiometric composition.

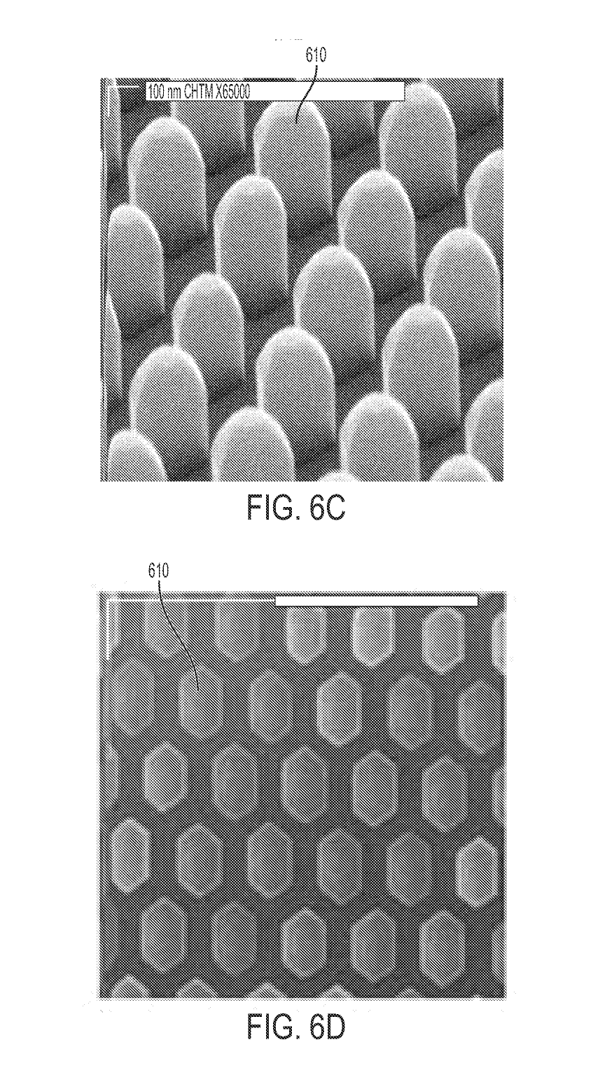

FIG. 5 depicts another exemplary semiconductor nanostructure device 500 including a buffer layer in accordance with the present teachings. As shown, the nanostructure device 500 can include a buffer layer 520 disposed between a substrate, such as the substrate 410, and a selective growth mask, such as the selective growth mask 435. The buffer layer 520 can be a similar layer to the buffer layer 220 shown in FIG. 2. The buffer layer 520 can be a planar film formed of, for example, GaN, AlN, InN or AlGaN, using, for example, standard MOCVD. In various embodiments, the thickness of the buffer layer 520 can be about 100 nm to about 100 micrometers (μm). In various embodiments the buffer layer 520 can be doped with either a p-type or n-type dopant in order to provide with an electrical connection to the lower end of each nanostructure.

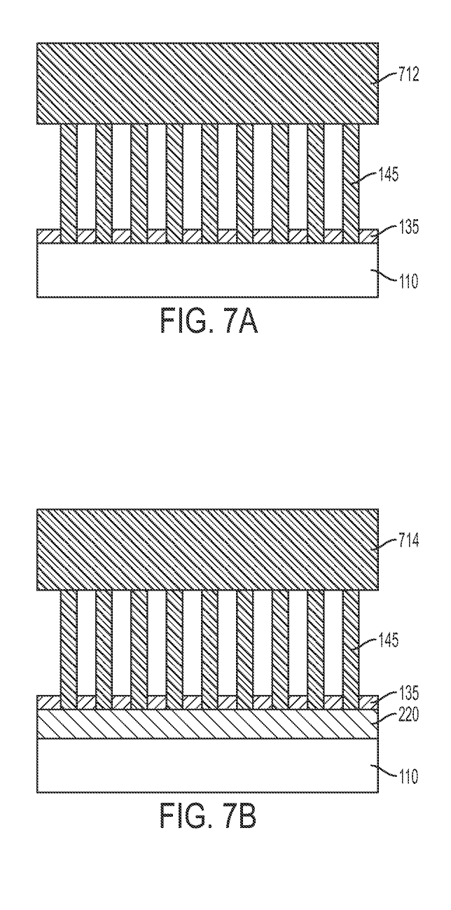

FIGS. 6A-6D depict exemplary results for the first two phases of growth (to be followed by additional pulsed and/or non-pulsed growth phases) for a plurality of ordered GaN nanostructures and/or nanostructure arrays without use of a catalyst. As shown in FIGS. 6A-6D, the plurality of GaN nanostructures 610 can grow with large scale uniformity of position, orientation, length, cross-sectional features (e.g., the dimensions and/or shapes), and crystallinity. As described herein, in some embodiments, the position and dimensions of each nanostructure can correspond with that of each aperture of the plurality of patterned apertures 138 shown in FIGS. 1-2. In other embodiments, the position and dimensions of each nanostructure can correspond with that of each top facet of the plurality of nanostructures 442 shown in FIGS. 4-5.

FIG. 6A shows a close-up scanning electron micrograph (SEM) result for the exemplary GaN nanostructures 610, while FIG. 6B shows a SEM result with long-range order for the GaN nanostructures 610. In various embodiments, each GaN nanostructure can have a single crystal nature.

FIG. 6C shows that the orientation of the GaN nanostructures 610 can be along a single crystal direction, for example, along the (0001) crystallographic direction of the exemplary GaN nanostructures 610. Additionally, the small central (0001) top facet of each nanostructure can be bounded by inclined {1102} facets on top of each nanostructure.

FIG. 6D is a plan view of the exemplary GaN nanostructures 610 showing the hexagonal symmetry of the sidewall facets of each GaN nanostructure. The sidewall facets can be perpendicular to the direction of the selective growth mask 620 having the sidewall facets of the {1100} family. In various embodiments, the diameter of the exemplary GaN nanostructures 610 can be about 20 nanometers (nm) or less.

The invariance of the lateral nanostructure geometry (e.g., the cross-sectional features) shown in FIGS. 6A-6D indicates that the GaN growth rate can only occur in the vertical direction, that is, on the (0001) and {1102} top facets. For example, the vertical growth rates for the plurality of GaN nanostructures 610 of the pulsed growth can be, for example, about 0.1 micrometers per hour (μm/hr) or higher. On the other hand, the GaN growth rate on the {1100} sidewall facets (i.e., lateral direction) can be essential negligible in spite of their much larger area. In an exemplary embodiment, the GaN nanostructures 610 can be grown having a uniform length of about 20 μm or higher and maintain a uniform diameter of about 250 nm or less, when a 30-nm-selective-growth-mask is used. In various embodiments, hydrogen incorporation in the carrier gas can be used to control the nanostructure geometry.

In addition, the exemplary uniform GaN nanostructures 610 shown in FIGS. 6A-6D can be of high-quality, that is, with essentially no threading dislocations (TD). For example, there can be no threading disclocations observed with the GaN nanostructures 145 and/or 445 shown in FIG. 2 and FIG. 5, even if the threading dislocations can be observed in the GaN buffer layer 220 and/or 520 underlying the selective growth mask 135 and/or 435. Furthermore, the defect-free GaN nanostructures 610 can be grown on various substrates, such as, for example, sapphire, silicon carbide such as 6H—SiC, or silicon such as Si (111).

In various embodiments, the uniform and high-quality GaN nanostructures and/or nanostructure arrays can be used for fabrication of high-quality GaN substrate structures. Commercially viable GaN substrates are desired because GaN substrates can greatly facilitate the fabrication of visible LEDs and lasers for the emerging solid-state lighting and UV sensor industries. Moreover, GaN-based substrates can also be used in other related applications, such as hi-power RF circuits and devices.

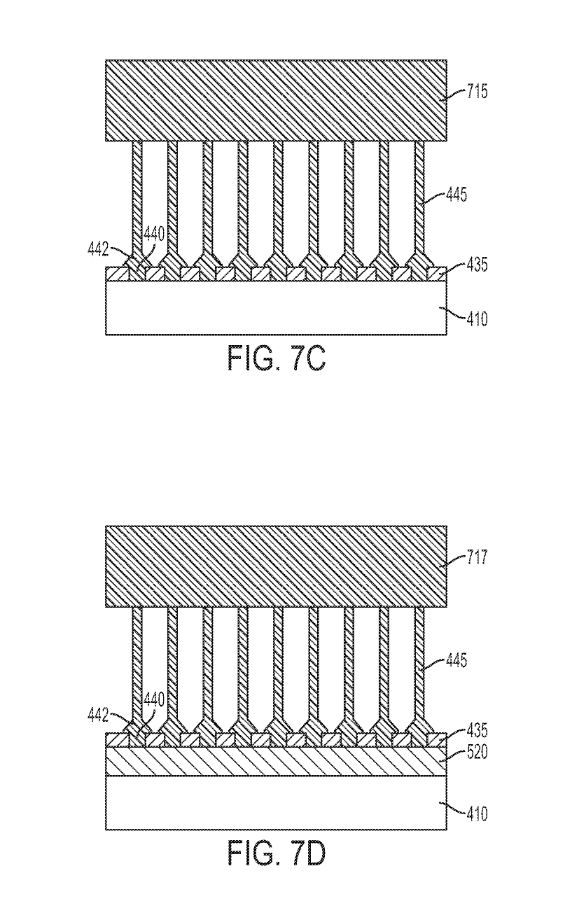

In various embodiments, GaN-based substrate structures can be formed by terminating and coalescing the plurality of GaN-based nanostructures such as those described in FIGS. 1-6 using techniques such as nanoheteroepitaxy. FIGS. 7A-7D depict four exemplary semiconductor devices including GaN-based substrate structures 712, 714, 715, and 717 formed from the plurality of GaN nanostructures of the device 100 (see FIG. 1C), the device 200 (see FIG. 2), the device 400 (see FIG. 4C), and the device 500 (see FIG. 5), respectively.

For example, the GaN growth conditions can be modified to allow coalescence of the formed plurality of nanostructures (e.g., 145 or 445) after they have grown to a suitable height, and then formation of a GaN-based substrate structure (e.g., the substrate 712, 714, 715, or 717). The GaN substrate structure can be a continuous, epitaxial, and fully coalesced planar film. The “suitable height” can be determined for each nanostructure (e.g., GaN) and substrate (e.g., SiC or Si) combination and can be a height that allows a significant reduction in defect density in the upper coalesced GaN film (i.e., the GaN substrate structure). In addition, the “suitable height” can be a height that can maintain a mechanically-robust structure for the resulting semiconductor devices, for example, those shown in FIGS. 7A-7D. In various embodiments, because threading defects are not present in the plurality of GaN-based nanostructures (e.g., 145 or 445), the coalescence of the GaN-based substrate structure (e.g., the substrate 712, 714, 715, or 717) on top of these pluralities of nanostructures can then occur and provide the GaN-based substrate structure containing an extremely low defect density, such as, for example, about 100 million defects per square centimeter or lower.

According to various embodiments of the nanostructure formation process, the process steps, (e.g., the deposition, patterning and etching of the selective growth mask, the selective growth of nanostructure nuclei, the pulsed growth of nanostructures, and the formation of the exemplary group III—Nitride substrate structures) can be scaleable to large substrate areas. They can also be readily extended to manufacturing requirements including automatic wafer handling and extended to larger size wafers for establishing efficacy of photonic crystals for light extraction from visible and near-UV LEDs.

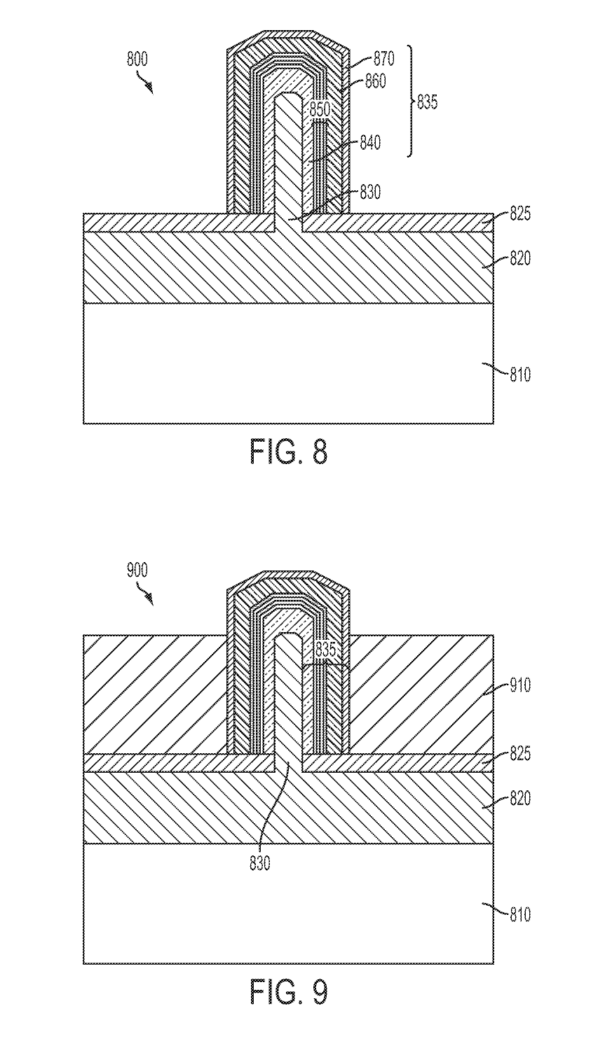

FIGS. 8-12 depict exemplary embodiments for nanostructure active devices including nanostructure LEDs and nanostructure lasers, and their scalable processes for manufacturing. In various embodiments, the disclosed Group III—Nitride nanostructures and nanostructure arrays such as GaN nanostructures and/or nanostructure arrays can provide their active devices with unique properties. This is because each pulsed-grown GaN nanostructure can have sidewalls of {1100} family and the normal to each of these side planes can be a nonpolar direction for Group III—Nitride materials. High-quality quantum Group III—Nitride wells such as quantum InGaN/GaN well, quantum AlGaN/GaN well or other quantum III-N wells, can therefore be formed on these side facets of each GaN nanostructure.

For example, the nanostructure growth behavior can be changed significantly when other precursor gases such as trimethylaluminum (Al) or trimethylindium (In) are added to the exemplary MOCVD gas phase during the pulsed growth mode. In this case, even a small molecular fraction (e.g., about 1%) of Al or In added to the GaN nanostructures and/or nanostructure arrays can result in each GaN nanostructure growing laterally with its cross-sectional dimensions (e.g., width or diameter) increasing over time. This lateral growth behavior can allow creation of a core-shell heterostructure, that is, quantum wells including exemplary materials of such as InGaN and AlGaN alloys can be grown on and envelop each GaN nanostructure core. As a result, the core-shell growth can create a core-shell nanostructure/MQW active structure for light emitting devices.

In various embodiments a third growth condition can be established to grow the core-shell of the exemplary InGaN and AlGaN alloys. This third growth mode can be a non-pulsed growth mode, as shown at 310 in FIG. 3.

In various embodiments, the core-shell nanostructure/MQW active structure can be used to provide high efficiency nanoscale optoelectronic devices, such as, for example, nanostructure LEDs and/or nanostructure lasers. For example, the resulting core-shell nanostructure/MQW active structure (i.e., having the MQW active shell on sidewalls of each nanostructure core) can be free from piezoelectric fields, and also free from the associated quantum-confined Stark effect (QCSE) because each nanostructure core has non-polar sidewalls. The elimination of the QCSE can increase the radiative recombination efficiency in the active region to improve the performance of the LEDs and lasers. Additionally, the absence of QCSE can allow wider quantum wells to be used, which can improve the overlap integral and cavity gain of the nanostructure based lasers. A further exemplary efficiency benefit of using the core-shell nanostructure/MQW active structure is that the active region area can be significant increased because of the unique core-shell structure.

FIG. 8 depicts a cross-sectional layered structure of an exemplary core-shell nanostructure/MQW active structure device 800 in accordance with the present teachings. It should be readily apparent to one of ordinary skill in the art that the device 800 depicted in FIG. 8 represents a generalized schematic illustration and that other materials/layers/shells can be added or existing materials/layers/shells can be removed or modified.

As shown, the device 800 can include a substrate 810, a buffer layer 820, a selective growth mask 825, a doped nanostructure core 830, and a shell structure 835 including a first doped shell 840, a MQW shell structure 850, a second doped shell 860, and a third doped shell 870.

The selective growth mask 825 can be formed over the buffer layer 820 over the substrate 810. The doped nanostructure core 830 can be connected to and extend from the buffer layer 820 through the selective growth mask 825, wherein the doped nanostructure core 830 can be isolated by the selective growth mask 825. The shell structure 835 can be formed to “shell” the doped nanostructure core 830 having a core-shell active structure, and the shell structure 835 can also be situated on the selective growth mask 825. In addition, the shell structure 835 can be formed by depositing the third doped shell 870 over the second doped shell 860, which can be formed over the MQW shell structure 850 over a first doped shell 840.

The substrate 810 can be a substrate similar to the substrates 110 and 410 (see FIGS. 1-2 and FIGS. 4-5) including, but not limited to, sapphire, silicon carbide, silicon and III-V substrates such as GaAs, or GaN.

The buffer layer 820 can be formed over the substrate 810. The buffer layer 820 can be similar to the buffer layers 220 and/or 520 (see FIG. 2 and FIG. 5). The buffer layer 820 can be formed of, for example, GaN, AlN, InN, AlGaN, InGaN or AlInGaN, by various crystal growth methods known to one of ordinary skill in the art. In various embodiments, the buffer layer 820 can be doped with a conductivity type similar to the doped nanostructure core 830. In some embodiments, the buffer layer 820 can be removed from the device 800.

The selective growth mask 825 can be a selective growth mask similar to the selective growth masks 135 and/or 435 (see FIGS. 1-2 and FIGS. 4-5) formed on the buffer layer 820. In various embodiments, the selective growth mask 825 can be formed directly on the substrate 810. The selective growth mask 825 can define the selective growth of the plurality of nanostructures and/or nanostructure arrays. The selective growth mask 825 can be formed of any dielectric material known to one of ordinary skill in the art.

The doped nanostructure core 830 can use any nanostructure of the plurality of nanostructures shown in FIGS.1-2 and FIGS. 4-7 formed using the multi-phase growth mode. The doped nanostructure core 830 can be formed of, for example, GaN, AlN, InN, AlGaN, InGaN or AlInGaN, which can be made an n-type by doping with various impurities such as silicon, germanium, selenium, sulfur and tellurium. In various embodiments, the doped nanostructure core 830 can be made p-type by introducing beryllium, strontium, barium, zinc, or magnesium. Other dopants known to one of ordinary skill in the art can be used. In various embodiments, the height of the doped nanostructure core 830 can define the approximate height of the active structure device 800. For example, the doped nanostructure core 830 can have a height of about 1 micrometer (μm) to about 1000 micrometers (μm).

The doped nanostructure core 830 can have non-polar sidewall facets of {1100} family (i.e., “m”-plane facets), when the material GaN is used for the doped nanostructure core 830. The shell structure 835 including the MQW shell structure 850 can be grown by core-shell growth on these facets and the device 800 can therefore be free from piezoelectric fields, and free from the associated quantum-confined Stark effect (QCSE).

The first doped shell 840 can be formed from and coated on the non-polar sidewall facets of the doped nanostructure core 830 by an exemplary core-shell growth, when the pulsed growth mode is used. For example, the first doped shell 840 can be formed by adding a small amount of Al during the pulsed growth of the doped nanostructure core 830 forming a core-shell heterostructure. The conductivity type of the first doped shell 840 and the doped nanostructure core 830 can be made similar, for example, an n-type. In various embodiments, the first doped shell 840 can include a material of AlₓGa₁₋ₓN, where x can be any number less than 1.00 such as 0.05 or 0.10.

The MQW shell structure 850 can be formed on the first doped shell 840 by the exemplary core-shell growth, when the pulsed growth mode is used. Specifically, the MQW shell structure 850 can be formed by adding a small amount of Al and/or In during the pulsed growth of the first doped shell 840 to continue the formation of the core-shell heterostructure. In various embodiments, the MQW shell structure 850 can include, for example, alternating layers of AlₓGa₁₋ₓN and GaN where x can be, for example, 0.05 or any other number less than 1.00. The MQW shell structure 850 can also include alternating layers of, for example, InₓGa₁₋ₓN and GaN, where x can be any number less than 1.00, for example, any number in a range from about 0.20 to about 0.45.

The second doped shell 860 can be formed on the MQW shell structure 850. The second doped shell 860 can be used as a barrier layer for the MQW shell structure 850 with a sufficient thickness of, such as, for example, about 500 nm to about 2000 nm. The second doped shell 860 can be formed of, for example, AlₓGa₁₋ₓN, where x can be any number less than 1.00 such as 0.20 or 0.30. The second doped shell 860 can be doped with a conductivity type similar to the third doped shell 870.

The third doped shell 870 can be formed by continuing the core-shell growth from the second doped shell 860 to cap the active structure device 800. The third doped shell 870 can be formed of, for example, GaN and doped to be an n-type or a p-type. In various embodiments, if the first doped shell 830 is an n-type shell, the second doped shell 860 and/or the third doped shell 870 can be a p-type shell and vice versa. In various embodiments, the third doped shell 870 can have a thickness of about 50 to about 500 nm.

During the growth of nanostructures 830 and core-shell structure 835, one or more subsequent growth mode transitions from the pulsed growth mode to the non-pulsed growth mode, as well as subsequent growth mode transitions from the non-pulsed growth mode to the pulsed growth mode and so on, are performed in order to more effectively incorporate group III—Nitride semiconductor compounds, such as GaN, AN, InN, InGaN, AlInGaN, or AlGaN, into the structure of the nanostructures 830 and core-shell structure 835, and in order to form devices 800 of the designed shape, size, diameter, length, morphology and stochiometric composition.

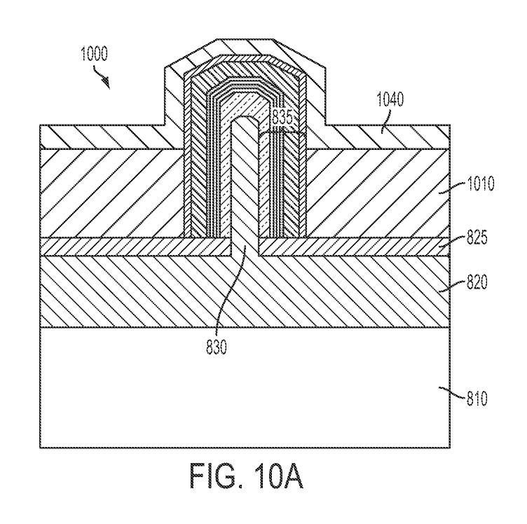

In various embodiments, the core-shell active structure devices 800 shown in FIG. 8 can be electrically isolated from each other, when a number of devices 800 are included in a large area such as a wafer. FIG. 9 depicts an active structure device 900 including a dielectric material 910 deposited to isolate each core-shell nanostructure/MQW active structure shown in FIG. 8 in accordance with the present teachings.

As shown in FIG. 9, the dielectric material 910 can be deposited on the selective growth mask 825 and laterally connected with the sidewalls of the shell structure 835, more specifically, the sidewalls of the third doped shell 870. In various embodiments, the dielectric material 910 can be any dielectric material for electrical isolation, such as, for example, silicon oxide (SiO₂), silicon nitride (Si₃N₄), silicon oxynitride (SiON), or other insulating materials. In some embodiments, the dielectric material 910 can be a curable dielectric. The dielectric material 910 can be formed by, for example, chemical vapor deposition (CVD) or spin-on techniques, with a desired height or thickness. In various embodiments, the height/thickness of the dielectric material 910 can be further adjusted by removing a portion of the dielectric material from the top of the deposited dielectric material using, for example, a lift-off procedure known to one of ordinary skill in the art. The thickness of the dielectric material 910 can be adjusted depending on specific applications where the core-shell nanostructure/MQW active structure is used.

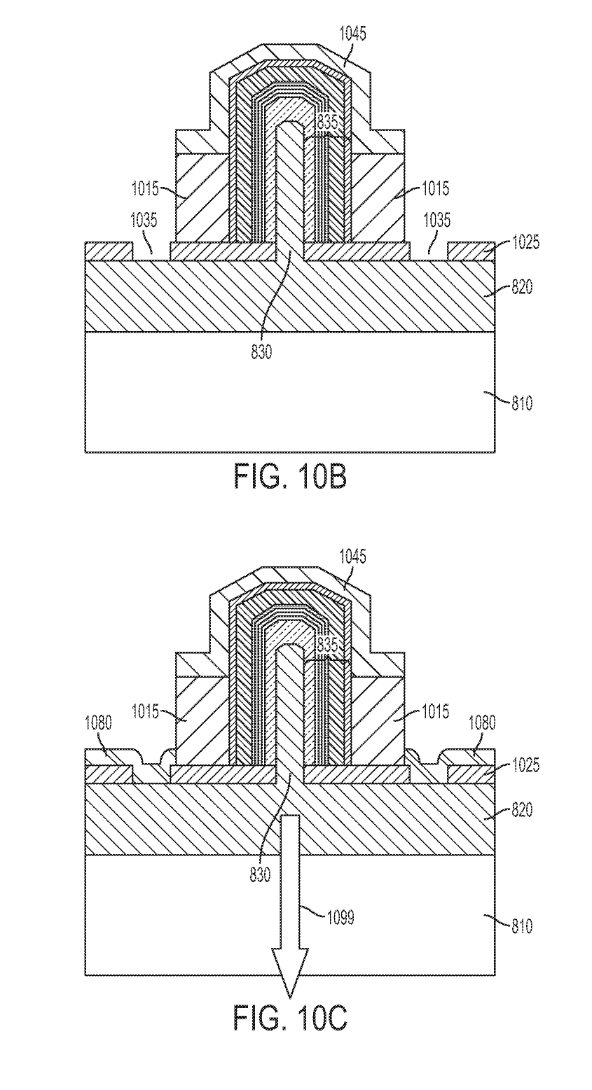

In various embodiments, various nanostructure LEDs and nanostructure lasers can be formed by the core-shell growth described in FIGS. 8-9, because MQW active shell structures can be created on the nonpolar sidewalls of the pulsed-grown nanostructures. For example, if the nanostructures are arranged in a hexagonal array with a pitch that is equal to λ/2, where λ is the emission wavelength of the exemplary LED or laser, the array of nanostructures can provide optical feedback to stimulate light-emitting action. FIGS. 10-12 depict exemplary nanoscale active devices formed based on the structures shown in FIGS. 8-9 in accordance with the present teachings.

FIGS. 10A-10C depict an exemplary nanostructure LED device 1000 using the core-shell nanostructure/MQW active structure described in FIGS. 8-9 in accordance with the present teachings.

In various embodiments, the nanostructure LED device 1000 can be fabricated including electrical contacts formed on, for example, the device 900. The electrical contacts can include conductive structures formed from metals such as titanium (Ti), aluminum (Al), platinum (Pt), nickel (Ni) or gold (Au) in a number of multi-layered combinations such as Al/Ti/Pt/Au, Ni/Au, Ti/Al, Ti/Au, Ti/Al/Ti/Au, Ti/Al/Au, Al or Au using techniques known to one of ordinary skill in the art.

In FIG. 10A, the device 1000 can include a conductive structure 1040 formed on the surface of the device 900, i.e., on each surface of the dielectric material 910 and the third doped shell 870 of the shell structure 835. The conductive structure 1040 can be a transparent layer used for a p-electrode of the LED device 1000 fabricated subsequently. In an exemplary embodiment, the conductive structure 1040 (or p-electrode) can be, for example, a layered metal combination of Ni/Au.

In various embodiments, the device 1000 can further include a dielectric layer 1010 having an adjusted thickness (or height). By adjusting the thickness of the dielectric layer 1010, the extent (e.g., thickness or height) of the conductive structure 1040 (or p-electrode) formed on and along the sidewall of the shell structure 835 can be adjusted according to the desired application of nanostructure active device. For example, a thick layer of the dielectric 1010 can confine the conductive structure 1040 (or p-electrode) to the top of the core-shell structured active devices, for example, for nanostructure LEDs and/or nanostructure lasers. Alternatively, an adjusted thin dielectric layer 1010 can allow the conductive structure 1040 (or p-electrode) to have a higher thickness or height (i.e., an increased extent), which can reduce the resistance of the active devices. In various embodiments, the higher thickness of the conductive structure 1040 (or p-electrode) can however be expected to contribute loss to the active devices such as laser cavity. As known to one of ordinary skill in the art, optimum performance of the conductive structure 1040 (or p-electrode) can be achieve by balancing the reduction of resistance of the active devices with the expected loss.

In various embodiments, the thickness of the conductive structure 1040 (or p-electrode) along the sidewalls of the shell structure 835 of the exemplary LED device 1000 can be in a range of about 0.1 micrometer (μm) to about 30 micrometers (μm) for a high efficiency performance. In various embodiments the LED device 1000 can have a total height of up to 100 micrometers (μm) or higher.

In FIG. 10B, the device 1000 can further include a p-electrode 1045, a dielectric 1015, and a selective growth mask 1025 having trenches 1035 converted from the selective growth mask 825.

The p-electrode 1045 and the underlying dielectric 1015 can be formed by patterning and etching the conductive structure 1040 and the dielectric layer 1010 (see FIG. 10A). As a result, portions (not shown) of surface of the selective growth mask 835 can be exposed and separated by the dielectric 1015 on both sides of each core-shell structure. After the patterning and etching processes, a selective growth mask 1025 can be formed by forming trenches 1035 through the exposed portions of surface of the selective growth mask 825, wherein each side of the core-shell active structure can include at least one trench 1035. As a result, surface portions of the underlying buffer layer 820 can be used as bottoms of the trenches 1035.

In various embodiments, the thickness of the selective growth mask 1025 can be critical for the performance of the LED device 1000. For example, a silicon nitride selective growth mask having a thickness of 30 nm can be sufficiently thick to support a voltage of about 20 Volts or higher before breakdown of the LED device 1000. In various embodiments, the selective growth mask 1025 can have a thickness of about 30 nm or less. However, one of ordinary skill in the art will understand that a thicker selective growth mask can be readily accommodated in the nanostructure and nanostructure active device processes.

In FIG. 10C, the device 1000 can include the n-electrodes 1080 formed to assure the conduction between the n-side contact and the central conductive region including the buffer layer 820 and the nanostructure core 830. The central conductive region can be, for example, a heavily doped n⁺ GaN region. In various embodiments, the n-electrodes 1080 can include conductive structures formed by depositing electrode materials onto each surface of the selective growth mask 1025 and the bottoms of the trenches 1035. In an exemplary embodiment, the n-electrodes 1080 can be formed of, for example, a layered metal combination, such as Al/Ti/Pt/Au.

At 1099, the resulting light of the nanostructure LED device 1000 in FIG. 10C can be extracted through the substrate 820, which can be transparent at green and blue wavelengths. In various embodiments, a more diffuse light output can occur on the top side of the device 1000 (not shown) since the nanostructure LED device 1000 can be small enough for sufficient diffraction. This diffuse light output can be advantageous in solid-state lighting applications.

In this manner, the disclosed nanostructure LED device 1000 can provide unique properties as compared with traditional LED devices. First, it can have a higher brightness because the core-shell grown active region area (i.e., the MQW active shell area) can be increased, for example, by a factor of approximately 10 times compared to a conventional planar LED structure. Second, the light extraction can be improved to increase the output efficiency of the LED. This is because the LED device's geometry can make the most of the active region area oriented normal to the wafer surface, i.e., the substrate surface. The confinement regions on either side of the MQW active region can tend to guide the LED light in the vertical direction. Third, because of the high precision of the position and diameter of each of the plurality of nanostructures and/or nanostructure arrays, the resulting arrays of the LED devices 1000 can also be configured as a photonic-crystal, which can further improve the light output coupling efficiency. Fourth, the nanostructure LED resistance can be significantly decreased because of the increase of the electrical contact area, for example, the contact area of the p-electrode 1045. Finally, since the LED device 1000 can provide a specified light power with higher brightness, more devices can be processed on a given wafer, which can decrease the cost of production and also increase the manufacture efficiency. For example to allow for metal contacts the LED device 1000 can include a pitch spacing (i.e., a center-to-center spacing between any two adjacent nanostructure devices) of for example 100 micrometers (μm), without any limitation to any other value. For example, a 4-inch diameter wafer can then include a number of nanostructure LED devices 1000, for example, about 0.78 million devices or more, which can be manufactured simultaneously. In various embodiments the pitch spacing between LED devices 1000 can be reduced further to allow a single 4-inch diameter wafer to contain, for example, more than one million LED devices 1000.

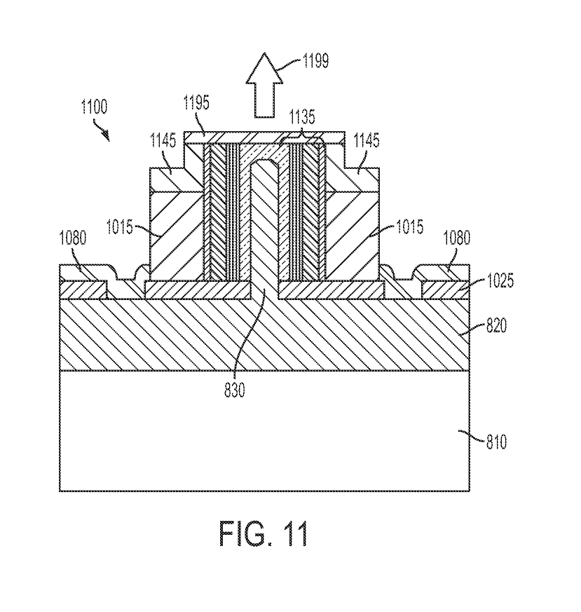

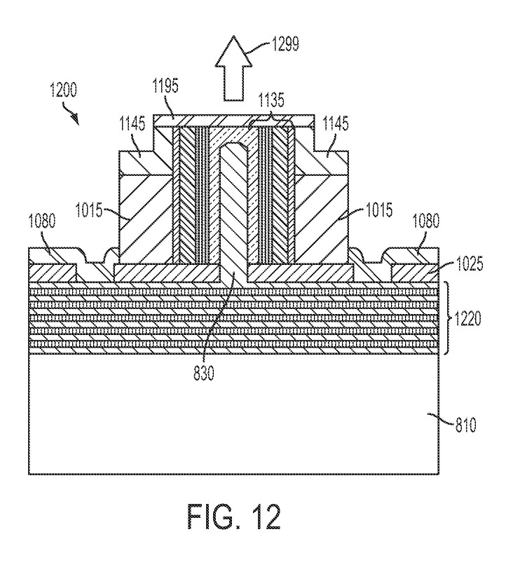

FIGS. 11-12 depict exemplary nanostructure laser devices using the core-shell grown nanostructure/MQW active structure shown in FIGS. 8-10 in accordance with the present teachings. Because the sidewall facets of the nanostructures and/or nanostructure arrays are exact {1100} facets with a flatness on the scale of an atomic monolayer, high quality MQW active regions for laser devices can be formed on these superior flat “sidewall substrates”. In addition, the vertical orientation of the sidewall facets and the uniform periodicity of the nanostructures can allow a photonic crystal optical cavity to be established straightforwardly, which can provide a high-throughput method of etching or cleaving facets to form an optical cavity.

As shown in FIG. 11, the nanostructure laser device 1100 can be fabricated from the processes described in FIGS. 8-10 using the core-shell grown nanostructure/MQW active structure as laser active structure. The nanostructure laser device 1100 can include a polished shell structure 1135, a polished p-electrode 1145, and a passivation layer 1195, which can be formed on each surface of the polished shell structure 1135 and the polished p-electrode 1145 to cap the laser active structure.

The polished shell structure 1135 and the polished p-electrode 1145 can be formed by polishing (i.e., removing) on the top end (with respect to the substrate 810 as the bottom end) of the core-shell nanostructure/MQW active structure (i.e., laser active structure) such as that shown in FIG. 10C. Various polishing processes, for example, a chemical-mechanical polishing, can be used using the etched dielectric 1015 as a mechanical support.

The polishing step can be used to polish a number of laser facets at the same time without diminishing the manufacturability of the nanostructure laser devices 1100. For example, a number of nanostructure laser devices 1100 such as about 0.78 million or more, can be formed on a 4-inch wafer for a high manufacturing efficiency. In various embodiments the pitch spacing can be reduced further to allow a single 4-inch wafer to contain, for example, more than one million laser devices 1100.

In various embodiments, the extent (e.g., thickness or height) of the polished p- electrode 1145 formed along the sidewalls of the polished shell structure 1135 can be adjusted by adjusting thickness of the underlying etched dielectric 1015 for optimum performance of the laser device 1100. In various embodiments, the thickness of the polished p-electrode 1145 along the sidewall of the polished shell structure 1135 shown in FIG. 11 can range from about 1 micrometer (μm) to about 5 micrometers (μm) when the overall height is about 10 micrometers (μm).

The passivation layer 1195 can be formed at the polished top end of each laser active structure, i.e., on each surface of the polished p-electrode 1145 and the polished shell structure 1135. The passivation layer 1195 can be configured to avoid undue non-radiative recombination or junction leakage of the nanostructure laser device 1100. In various embodiments, the passivation layer 1195 can be formed of, for example, any dielectric material known to one of ordinary skill in the art with a thickness of about 10 to 100 nanometers (nm) or larger.

In some embodiments, the composition and refractive index of the materials used for the polished shell structure 1135 surrounding the nanostructure cavity (i.e., the nanostructure core 830) can affect the optical lasing process at 1199. For example, when the nanostructures have an exemplary diameter of about 200 nm, some of the optical lasing mode can exist outside the cavity. The laser can therefore be more sensitive to the composition and refractive index of the materials surrounding the cavity, that is, materials used for each layer of the polished shell structure 1135.

In other embodiments, because there is no physical lower facet on the laser optical cavity (i.e., the nanostructure core 830), there can be a change of effective refractive index in the vicinity of the selective growth mask 1025. This index change can in fact be helped (i.e., made larger) by the fact that some of the optical lasing mode can exist outside the cavity. In an exemplary embodiment, the nanostructure laser device 1100 (see FIG. 11) can be optically tuned by adjusting the thickness of the selective growth mask 1025 for a maximum reflectivity. For example, the thickness of the selective growth mask 1025 for the laser device 1100 can be in a range of about 220 nanometers (nm) to about 230 nanometers (nm) when the device emits blue light at 450 nm.

FIG. 12 depicts another exemplary laser device 1200, in which a distributed Bragg reflector (DBR) mirror stack 1220 can be disposed between the layers of the substrate 810 and the selective growth mask 1025, as opposed to the buffer layer 820 being disposed between these two layers of the laser device 1100 shown in FIG. 11.

The DBR mirror stack 1220 can be an epitaxial DBR mirror stack. The DBR mirror stack 1220 can include, for example, quarter-wave alternating layers of, for example, GaN and AlGaN. In various embodiments, the DBR mirror stack 1220 can be tuned to improve reflectivity and to increase cavity Q of the laser 1299.

In various embodiments, all the nanostructure active devices shown in FIGS. 10-12 can provide a low device resistance because more resistive p-electrodes (e.g., the p-electrode 1045 and/or 1145) of the heterostructure can be located at the larger-area, which is outer periphery of each core-shell nanostructure/MQW active structure. For example, for the LED device 1000 (shown in FIG. 10), the p-electrode 1045 can be patterned to completely cover the top of the device 1000 to further decrease the device resistance.

Although a single nanostructure is depicted in FIGS. 8-12 for the purpose of description, one of ordinary skill in the art will understand that the core-shell growth processes on each nanostructure of the plurality of nanostructures and/or nanostructure arrays (e.g., shown in FIGS. 1-6) for nanoscale active devices can be simultaneously conducted in a large area (e.g., a whole wafer).

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A method of making group III—Nitride semiconductor nanostructures comprising:
forming a selective growth mask over a substrate, wherein the selective growth mask comprises a plurality of patterned apertures that exposes a plurality of portions of the substrate;
using a selective first non-pulsed growth mode to grow a semiconductor material on each of the plurality of portions of the substrate;
performing a first growth-mode transition from the first non-pulsed to a first pulsed growth mode;
forming a plurality of group III—Nitride semiconductor nanostructures by continuing the first pulsed growth mode of the semiconductor material;
performing a second growth-mode transition from the first pulsed growth mode to a second non-pulsed growth mode; and
continuing the formation of the group III—Nitride semiconductor nanostructures by continuing the second non-pulsed growth mode of the semiconductor material.

2. The method of claim 1, wherein the substrate comprises a buffer layer over a supporting substrate surface and the semiconductor material is selectively grown through the plurality of patterned apertures on the buffer layer.

3. The method of claim 1, wherein the substrate comprises one or more materials selected from the group consisting of silicon (Si), silicon carbide (SiC), sapphire, GaN, InN, AN, InGaN, AlGaN, InGaAlN and GaAs.

4. The method of claim 1, further comprising one or more cleaning processes prior to the selective growth of the semiconductor material.

5. The method of claim 1, wherein the plurality of patterned apertures forms a hexagonal array having a diameter of about 10 nm to about 500 micrometers (μm) and a pitch of about 20 nm to about 1000 micrometers (μm).

6. The method of claim 1, wherein a cross-sectional feature of each of the plurality of group III—Nitride semiconductor nanostructures and each of the plurality of patterned apertures is substantially similar.

7. The method of claim 6, wherein the cross-sectional feature is a shape selected from the group consisting of a polygon, a rectangle, a square, an oval, and a circle.

8. The method of claim 6, wherein the step of performing a first growth-mode transition from the first non-pulsed growth mode to the first pulsed growth mode occurs before growth of the semiconductor material protrudes over a top of the selective growth mask.

9. The method of claim 1, wherein the material for the plurality of semiconductor nanostructures comprises one or more group III—Nitride materials selected from the group consisting of GaN, AN, InN, InGaN, AlInGaN and AlGaN.

10. The method of claim 1, wherein the growth of the group III—Nitride semiconductor nanostructures is conducted by using at least one of the following methods: Metal Organic Chemical Vapor Deposition (MOCVD); Vapor Phase Epitaxy; Hydride Vapor Phase Epitaxy (HVPE); OrganoMetallic pyrolysis in Vapor Phase Epitaxy (OMVPE); Close Space vapor Transport (CSVT); and Molecular Beam Epitaxy (MBE).

11. The method of claim 1, wherein the selective first non-pulsed growth comprises Group III and Group V precursor gases having a III/V ratio ranging from about 100 to about 5000.

12. The method of claim 1, wherein the first pulsed growth comprises alternately introducing Group III and Group V precursor gases of the semiconductor material in a growth reactor with one or more sequence loops, wherein the precursor gases comprise a III/V ratio ranging from about 50 to about 5,000.

13. The method of claim 1, wherein the first pulsed growth comprises a vertical growth rate of about 0.1 micrometers (μm) per hour or higher.

14. The method of claim 1, wherein each of the plurality of group III—nitride semiconductor nanostructures has a length of about 10 nm to about 10,000 micrometers (μm).

15. The method of claim 1, wherein:
the step of the first growth-mode transition from the first non-pulsed growth mode to the first pulsed growth mode occurs after growth of the semiconductor material protrudes over a top of the selective growth mask to form a plurality of truncated pyramid-shaped nanostructures partially disposed on a surface of the selective growth mask; and
the step of forming the plurality of group III—Nitride semiconductor nanostructures comprises forming a semiconductor nanostructure on each of the plurality of pyramid-shaped nanostructures by continuing the first pulsed growth of the semiconductor material such that a cross-sectional feature of the semiconductor nanostructure and a top facet of each of the plurality of pyramid-shaped nanostructures is substantially similar.

16. The method of claim 15, wherein the group III—nitride semiconductor nanostructure comprises a cross-sectional dimension smaller than that of each of the plurality of patterned apertures.

17. The method of claim 1, further comprising:
performing additional growth-mode transitions from non-pulsed growth mode to pulsed growth mode and from pulsed growth mode to non-pulsed growth mode; and
continuing the formation of the plurality of group III—nitride semiconductor nanostructures by continuing the pulsed growth mode or non-pulsed growth mode, as applicable, of the semiconductor material after each growth-mode transition; until group III—Nitride semiconductor nanostructures of the designed shape, size, morphology and stochiometry are formed.

18. A group III-Nitride semiconductor nanostructure array formed by the method of claim 1, comprising:
a support comprising a plurality of selected surface regions;
a group III—Nitride semiconductor nanostructure connected to and extending from each of the plurality of selected surface regions of the support, wherein the group III—Nitride semiconductor nanostructure is oriented along a single direction and maintains a cross-sectional feature of one of the plurality of selected surface regions.

19. The nanostructure array of claim 18, further comprising a GaN nanostructure oriented along the (0001) crystallographic direction.

20. The nanostructure array of claim 18, wherein the group III—Nitride semiconductor nanostructure comprises one or more materials selected from the group consisting of GaN, AN, InN, InGaN, AlGaN, AlInGaN.

21. The nanostructure array of claim 18, wherein the group III—Nitride semiconductor nanostructure comprises one or more cross-sectional shapes selected from the group consisting of a polygon, a rectangle, a square, an oval, and a circle.

22. The nanostructure array of claim 18, wherein the group III—Nitride semiconductor nanostructure further comprises an aspect ratio of about 5 or higher and a cross sectional dimension of about 10 nm (nanometers) or larger.

23. The nanostructure array of claim 18, wherein the support comprises a Group III—Nitride semiconductor nanostructure nucleus disposed on each of a plurality of portions of a substrate through a selective growth mask disposed on the substrate, wherein a surface of the Group III—Nitride semiconductor nanostructure nucleus comprises one of the plurality of selected surface regions of the support.

24. The nanostructure array of claim 23, wherein the support further comprises a pyramid-shaped Group III—Nitride semiconductor nanostructure formed from the Group III—Nitride nanostructure nucleus and partially disposed on the selective growth mask, wherein a top facet of the pyramid-shaped Group III—Nitride nanostructure comprises one of the plurality of selected surface regions of the support.

25. A group III—Nitride semiconductor substrate structure comprising:
a group III—nitride semiconductor nanostructure array formed by the method of claim 1 comprising a plurality of group III—nitride semiconductor nanostructures, wherein each of the plurality of semiconductor nanostructures is defect-free or largely defect-free; and
a group III—nitride semiconductor film coalesced from the plurality of group III—Nitride semiconductor nanostructures, wherein the semiconductor film has a defect density of about 100 million defects per square centimeter, or lower.

26. The substrate of claim 25, wherein the group III—Nitride semiconductor film comprises one or more materials selected from the group consisting of GaN, AN, InN, InGaN, AlGaN, AlInGaN.

27. A substrate comprising a plurality of group III—Nitride semiconductor nanostructures formed by the method of claim 1.
